(19) United States
(12) Patent Application Publication
(10) Pub. No.: US 2014/0374249 A1
(43) Pub. Date: Dec. 25, 2014

(54) ANODE FOR OXYGEN GENERATION AND MANUFACTURING METHOD FOR THE SAME

(71) Applicant: INDUSTRIE DE NORA S.P.A., Milano (IT)

(72) Inventors: Yi Cao, Kanagawa (JP); Akihiro Kato, Kanagawa (JP); Kazuhiro Hirao, Kanagawa (JP); Takashi Furusawa, Kanagawa (JP)

(21) Appl. No.: 14/368,608

(22) PCT Filed: Dec. 25, 2012
(86) PCT No.: PCT/JP2012/084260

§ 371 Date: Jun. 25, 2014

(30) Foreign Application Priority Data
Dec. 26, 2011 (JP) 2011-283847

(51) Int. Cl. C25B 11/04; C23C 14/32; C25B 1/02

(52) U.S. Cl. CPC C25B 11/0473; C25B 11/0484; C25B 1/02; C25B 11/0431; C23C 14/325
USPC 204/290.08; 204/290.14; 427/126.5; 204/192.38

(57) ABSTRACT

The present invention aims to provide an anode for oxygen generation and a manufacturing method for the same used for industrial electrolyses including manufacturing of electrolytic metal foils such as electrolytic copper foil, aluminum liquid contact and continuously electrogalvanized steel plate, and metal extraction. The present invention features an anode for oxygen generation and a manufacturing method for the same comprising a conductive metal substrate and a catalyst layer containing iridium oxide formed on the conductive metal substrate wherein the coating is baked in a high temperature region of 410° C.-450° C. in an oxidation atmosphere to form the catalyst layer co-existing amorphous and crystalline iridium oxide and the catalyst layer co-existing the amorphous and crystalline iridium oxide is post-baked in a further high temperature region of 520° C.-560° C. in an oxidation atmosphere to crystallize almost all amount of iridium oxide in the catalyst layer.

### TECHNICAL FIELD

The present invention relates to an anode for oxygen generation used for various industrial electrolyses and a manufacturing method for the same; more in detail, it relates to a high-load durable anode for oxygen generation and a manufacturing method for the same used for industrial electrolyses including manufacturing of electrolytic metal foils such as electrolytic copper foil, aluminum liquid contact, and continuously electrogalvanized steel plate, and metal extraction.

### BACKGROUND ART

Mixing of lead ions in the electrolytic cell is often seen in various types of industrial electrolysis. Mixing of lead compounds in the production of electrolytic copper foil as its typical example is derived from the following two points: that is, sticking to, as a lead alloy, a scrap copper which is one of the raw materials of copper sulfate in electrolyte, and before DSE (registered trademark of Permelec Electrode Ltd.) type of electrode being used, lead-antimony electrodes were used, this time of leaching lead ions become lead sulfate particles and residue in electrolytic cell.

High purity electrolytic copper is best for raw materials, but in a practical manner, scrap copper which is recycled products is often used. Copper raw material is leached as copper ion by using concentrated sulfuric acid as an immersion liquid, or the copper raw material is compulsory eluted as anode for a short time. In an anodic dissolution, elution becomes easy from the complex morphology of clad metals and other metal parts. In a scrap copper, wax materials such as lead soldering material is adhered, and other metals included in the wax materials or the clad is eluted with elution of copper in the electrolyte of a sulfuric acid-copper sulfate, or is mixed as floating particles. To the surface of the metal lead, a water-insoluble lead sulfate coating is formed, and so lead ion is high corrosion resistance to sulfuric acid, but a small amount of it is dissolved in a concentrated sulfuric acid, and such lead ion crystallizes as a minute particle of lead sulfate in electrolyte and floats under a lower temperature than that in dissolving and a high pH conditions.

Still more, lead sulfate, PbSO₄, is a water-insoluble salt in which a solubility product is 1.06×10⁻⁸ mol/L (18° C.), and is extremely small in which a solubility in 10% sulfuric acid and 25° C. is approximately 7 mg/L.

Incidentally a standard electrode potential of copper is high after the precious metal (Cu²⁺+2e⁻→Cu: +0.342V vs. SHE) and a potential difference compared with base metal such as lead and etc. is great (Pb²⁺+2e⁻→Pb: −0.126V vs. SHE), and as overvoltage of copper in electro deposition is also low, there is no hydrogen evolution and no eutectoid with other base metals. That is why scrap copper can be used as raw materials.

However, an influence by floating fine particles such as lead ion, Pb²⁺, or lead compounds, PbSO₄ Against an electrode for electrolysis and an electrolytic copper foil which is an electrolytic product cannot be made light of.

Namely, in an electrode for electrolysis (anode), if electrolysis occurs, lead-ion, Pb²⁺, is oxidized to lead-β-PbO₂ in acidic solution, and electrodeposited to a surface of the electrode (anode) catalyst (Pb²⁺/PbO₂: pH=nearly 0, E₀=approximately 1.47V vs. SHE) (exactly 1.459+0.0295 p (Pb²⁺)-0.1182 pH). Since oxidized lead-β-PbO₂ has a small electrode catalyst function, a total surface of an electrode is covered by it, although an electrode potential increases, an electrolysis continuously occurs and an electrode life as a coating to protect the electrode is prolonged, but if it is partially peeled off, an original electrode catalyst layer of which catalyst activity is high, is exposed, and therefore an electrolysis current of it increases and an unevenness of a foil thickness of copper foil growing on an opposite cathode drum is caused.

Also, an electrolysis stops and an electrode continues to be immersed in the electrolyte and lead oxide is easily reduced to lead sulfate, PbSO₄ having no electrode catalyst activity to correspond to oxidation reaction of a trace oxygen evolution by the action of local battery (PbSO₄+2H₂O=PbO₂+HSO₄⁻+3H⁺+2e⁻: at pH=nearly 0, E₀=approximately 1.62V vs. SHE) (exactly 1.632−0.0886 pH-0.0295 p(HSO₄⁻)) and so a problem that electrolysis voltage rises after electrolysis appears.

Also, the following problem occurs: Fine particles of PbSO₄ floating in the electrolyte adhere to the surface of the electrolytic copper foil and are embroiled in a roll of electrolytic copper foil.

In recent years from the environmental point of view, in all aspects of raw materials of electrolyte, equipment and waste matter and etc., the consciousness that is going to make lead-free is increasing. However, after a lead-free solder penetrated, there is time lag up to replace to scrap copper of the lead-free and in the point of cost, it is predicted that the coexistence with the lead ion continues for a while now. In the electrode for electrolysis, therefore, it is necessary to reduce the influence of the lead ion such as the above as much as possible.

Furthermore, as an electrode for this kind of electrolysis, together with reducing the influence of the lead ion as much as possible, electrode with a low oxygen generation potential and a long service life is required. Conventionally, as electrode of this type, an insoluble electrode comprising a conductive metal substrate, such as titanium, covered with a catalyst layer containing precious metal or precious metal oxide has been applied. For example, PTL 1 discloses an insoluble electrode prepared in such a manner that a catalyst layer containing iridium oxide and valve metal oxide is coated on a substrate of conductive metals, such as titanium, heated in oxidizing atmosphere and baked at a temperature of 650° C.-850° C., to crystallize valve metal oxide partially. This electrode, however, has the following drawbacks. Since the electrode is baked at a temperature of 650° C. or more, the metal substrate, such as of titanium causes interfacial corrosion and becomes poor conductor, causing oxygen overvoltage to increase to an unserviceable degree as electrode. Moreover, the crystallite diameter of iridium oxide in the catalyst layer enlarges, resulting in decreased the electrode effective surface area of the catalyst layer, leading to a poor catalytic activity.

PTL 2 discloses use of an anode for copper plating and copper foil manufacturing prepared in such a manner that a catalyst layer comprising amorphous iridium oxide and amorphous tantalum oxide in a mixed state is provided on a substrate of conductive metal, such as titanium. This electrode, however, features amorphous iridium oxide, and is insufficient in electrode durability. The reason why durability decreases when amorphous iridium oxide is applied is that amorphous iridium oxide shows unstable bonding between iridium and oxygen, compared with crystalline iridium oxide.

PTL 3 discloses an electrode coated with a catalyst layer comprising a double layer structure by a lower layer of crystalline iridium oxide and an upper layer of amorphous iridium oxide, in order to suppress consumption of the catalyst layer and to enhance durability of the electrode. The electrode disclosed by PTL 3 is insufficient in electrode durability because the upper layer of the catalyst layer is amorphous iridium oxide. Moreover, crystalline iridium oxide exists only in the lower layer, not uniformly distributed over the entire catalyst layer, resulting in insufficient electrode durability.

PTL 4 discloses an anode for zinc electrowinning in which a catalyst layer containing amorphous iridium oxide as a prerequisite and crystalline iridium oxide, as a mixed state is provided on a substrate of conductive metal like titanium. PTL 5 discloses an anode for cobalt electrowinning in which a catalyst layer containing amorphous iridium oxide as a prerequisite and crystalline iridium oxide, as a mixed state is provided on a substrate of conductive metal like titanium. However, it is thought that electrode durability of these two electrodes is not enough because they contain a large amount of amorphous iridium oxide, as a prerequisite.

### CITATION LIST

### Patent Literature

PTL 1: JP2002-275697A (JP3654204B)
PTL 2: JP2004-238697A (JP3914162B)
PTL 3: JP2007-146215A
PTL 4: JP2009-293117A (JP4516617B)
PTL 5: JP2010-001556A (JP4516618B)

### SUMMARY OF INVENTION

### Technical Problem

In order to solve the above-mentioned problems, the present invention aims to provide an anode for oxygen generation and a manufacturing method for the same, which can reduce the oxygen overvoltage of the anode for oxygen evolution to use for production of an electrode for industrial electrolysis to coat the electrolysis active substance layer particularly the electrolysis copper foil and metal winning by the electrolytic method and control adhesion, coating of the lead dioxide to the anode and raise the durability.

### Solution to Problem

As the first solution to achieve the above-mentioned purposes, the present invention provides an anode for oxygen generation comprising a conductive metal substrate and a catalyst layer containing iridium oxide formed on the conductive metal substrate, wherein the coating is baked in a high temperature region of 410° C.-450° C. in an oxidation atmosphere to form the catalyst layer coexisting amorphous and crystalline iridium oxides and the catalyst layer coexisting the amorphous and crystalline iridium oxides is post-baked in a further high temperature region of 520° C.-560° C. in an oxidation atmosphere to crystallize almost all amount of iridium oxide in the catalyst layer.

As the second solution to achieve the above-mentioned purposes, the present invention provides an anode for oxygen generation comprising a conductive metal substrate and a catalyst layer containing iridium oxide formed on the conductive metal substrate, wherein the degree of crystallinity of iridium oxide in the catalyst layer after the post-baking is made to be 80% or more.

As the third solution to achieve the above-mentioned purposes, the present invention provides an anode for oxygen generation comprising a conductive metal substrate and a catalyst layer containing iridium oxide formed on the conductive metal substrate wherein the crystallite diameter of iridium oxide after the post-baking in the catalyst layer is 9.7 nm or less.

As the fourth solution to achieve the above-mentioned purposes, the present invention provides an anode for oxygen generation comprising a conductive metal substrate and a catalyst layer containing iridium oxide formed on the conductive metal substrate, wherein an arc ion plating (hereafter called AIP) base layer containing tantalum and titanium ingredients is formed by AIP process on the conductive metal substrate before the formation of the catalyst layer.

As the fifth solution to achieve the above-mentioned purposes, the present invention provides a manufacturing method for an anode for oxygen generation, wherein the catalyst layer coexisting amorphous and crystalline iridium oxides is formed on the surface of the conductive metal substrate by baking in a high temperature region of 410° C.-450° C. in an oxidation atmosphere and the catalyst layer coexisting amorphous and crystalline iridium oxides is post-baked in a further high temperature region of 520° C.-560° C. in an oxidation atmosphere to crystallize almost all amount of iridium oxide in the catalyst layer.

As the sixth solution to achieve the above-mentioned purposes, the present invention provides a manufacturing method for an anode for oxygen generation, wherein the catalyst layer coexisting amorphous and crystalline iridium oxides is formed on the surface of the conductive metal substrate by baking in a high temperature region of 410° C.-520° C. in an oxidation atmosphere and the catalyst layer coexisting amorphous and crystalline iridium oxides is post-baked in a further high temperature region of 520° C.-560° C. in an oxidation atmosphere to make the degree of crystallinity of iridium oxide in the catalyst layer to be 80% or more.

As the seventh solution, to achieve the above-mentioned purposes, the present invention provides a manufacturing method for an anode for oxygen generation, wherein the catalyst layer coexisting amorphous and crystalline iridium oxide is formed on the surface of the conductive metal substrate by baking in a high temperature region of 410° C.-450° C. in an oxidation atmosphere and the catalyst layer coexisting amorphous and crystalline iridium oxides is post-baked in a further high temperature region of 520° C.-560° C. in an oxidation atmosphere to make the crystallite diameter of iridium oxide in the catalyst layer to be 9.7 nm or less.

As the eighth solution to achieve the above-mentioned purposes, the present invention provides a manufacturing method for an anode for oxygen generation comprising a conductive metal substrate and a catalyst layer containing iridium oxide formed on the conductive metal substrate, wherein the AIP base layer containing tantalum and titanium ingredients is formed by the AIP process on the conductive metal substrate before the formation of the catalyst layer.

### Advantageous Effects of Invention

In the formation for the electrode catalyst layer containing iridium oxide by the present invention, baking is conducted, instead of the conventional repeated baking operations at 500° C. or more, which are the perfect crystal deposition temperature, by two steps: coating and baking is repeated in a high temperature region of 410° C.-450° C. in an oxidation atmosphere to form the electrode catalyst layer coexisting amorphous and crystalline iridium oxides and the catalyst layer coexisting amorphous and crystalline iridium oxides is post-baked in a further high temperature region of 520° C.-560° C. in an oxidation atmosphere to suppress the crystallite diameter of iridium oxide in the electrode catalyst layer preferably to 9.7 nm or less and to crystallize most of the iridium oxide preferably to 80% or more in crystallinity. Thus, the growth of crystallite diameter of iridium oxide and coexistence of amorphous and crystalline iridium oxides was able to be suppressed and the electrode effective surface area of the catalyst layer was able to be increased. Thus, according to the present invention, the growth of crystallite diameter of iridium oxide can be suppressed. As the reasons, the following are considered. The baking is conducted by two stages: first, coating and baking is repeated in a high temperature region of 410° C.-450° C. in an oxidation atmosphere and then post-baking in a further high temperature of 520° C.-560° C. in an oxidation atmosphere. Compared with the baking at a high temperature from the beginning by the conventional method, crystallite diameter under the present invention will not enlarge beyond a certain degree. If the growth of crystallite diameter of iridium oxide is suppressed, the smaller the crystallite diameter is, the larger the electrode effective surface area of the catalyst layer will be. Then, the oxygen generation overvoltage of the electrode can be decreased, oxygen generation is promoted, and the reaction to form PbO₂ from lead ion can be suppressed. In this way, PbO₂ attachment and covering on the electrode were suppressed. Furthermore, according to the present invention, by increasing the electrode effective surface area of the catalyst layer, the current distribution is dispersed at the same time and the current concentration is suppressed and also wear rate of the catalyst layer by electrolysis can be suppressed, and then the durability of the electrode is improved.

### BRIEF DESCRIPTION OF DRAWINGS

FIG. 1 is a graph indicating the change of degree of crystallinity of iridium oxide (IrO₂) of the catalyst layer by baking temperature and post-bake temperature.

FIG. 2 is a graph indicating the change of crystallite diameter of iridium oxide (IrO₂) of the catalyst layer by baking temperature and post-bake temperature.

FIG. 3 is a graph indicating the change of the electrostatic capacity of the electrode by baking temperature and post-bake temperature.

FIG. 4 is a graph indicating the dependence of oxygen overvoltage on baking conditions.

### DESCRIPTION OF EMBODIMENTS

The following explains embodiments of the present invention, in detail, in reference to the figures. In the present invention, it is found that if the electrode effective surface area of the electrode catalyst layer is increased to suppress adhesive reaction of lead oxide to the electrode surface, oxygen generation overvoltage can be reduced and then, oxygen generation is promoted and at the same time the adhesive reaction of lead oxide can be suppressed. In addition, the present invention has been completed from the idea that it is necessary that iridium oxide of the catalyst layer is mainly crystalline in order to improve the electrode durability at the same time, and experiments were repeated.

In the present invention, a two-step baking is performed, first, in a high temperature region of 410° C.-450° C. in an oxidation atmosphere to form a catalyst layer coexisting amorphous and crystalline IrO₂ in the baking, then, in a further high temperature region of 520° C.-560° C. in an oxidation atmosphere to post-bake, through which the iridium oxide of the catalyst layer is almost completely crystallized.

Through the experiments conducted by inventors of the present invention, it has been proved that the catalyst layer containing amorphous iridium oxide, which can greatly increase the electrode effective surface area, consumes amorphous iridium oxide quite rapidly by electrolysis and durability is reduced relatively. In other words, it is considered that the electrode durability cannot be improved unless iridium oxide of the catalyst layer is crystallized. Therefore, in order to achieve the purpose of the present invention that the electrode effective surface area of the electrode catalyst layer is increased and the overvoltage of the electrode is reduced, the present invention applies two-step baking: high temperature baking plus high temperature post-baking in order to control the crystallite diameter of iridium oxide of the catalyst layer, through which iridium oxide crystal, smaller in size than the conventional product precipitates, resulting in increased the electrode effective surface area of the electrode catalyst layer and reduced overvoltage. In addition, It was found that in the catalyst layer of the electrode manufactured by the baking method of the present invention, a small amount of an amorphous iridium oxide exists, but that such a small amount of an amorphous iridium oxide is effective for an increase of the electrode effective surface area and does not give a big influence on the electrode durability (by the electrolysis evaluation in the pure sulfuric acid).

In the present invention, a catalyst layer containing coexisting amorphous and crystalline iridium oxide is formed on the surface of the conductive metal substrate by baking in a high temperature region of 410° C.-450° C. in an oxidation atmosphere; thereafter, the catalyst layer of amorphous and crystalline iridium oxides is post-baked in a further high temperature region of 520° C.-560° C. in an oxidation atmosphere to crystallize the Iridium oxide in the catalyst layer almost completely.

The coating amount of iridium oxide by the present invention is preferable to control to 2.0 g/m² or less per time as a metal. This amount is determined by electrolytic conditions and an ordinal electrolysis is performed at a current density of 50 A/dm²-130 A/dm² And in this case, a coating amount of iridium oxide of 1.0-2.0 g/m² per time as a metal is used, and a coating times is ordinarily 10-15 times and a total amount is 10-30 g/m².

The baking temperature in a high temperature region of 410° C.-450° C. in an oxidation atmosphere and the post-baking temperature in a further high temperature region of 520° C.-560° C. in an oxidation atmosphere are determined by the crystal particle size and the degree of crystallinity of iridium oxide to be formed in the catalyst layer, and the catalyst layer with a low oxygen overvoltage and a high corrosion resistance is formed in the above-mentioned temperature region.

In the present invention, the degree of crystallinity of the iridium oxide of the catalyst layer is preferably to 80% or more and if it being less than this value, the amorphous iridium oxide of the catalyst layer becomes more and the iridium oxide of the catalyst layer become unstable and a sufficient durability is not obtained. Also the crystallite diameter of iridium oxide in the catalyst layer is preferably equal to or less than to 9.7 nm and if it being more than this value, the electrode effective surface area iridium oxide of the catalyst layer becomes smaller and the oxygen generation overvoltage of the electrode increases and a reaction of generation of PbO₂ from lead ions is not suppressed.

Prior to forming the catalyst layer, if the AIP base layer is provided on the conductive metal substrate, it is possible to prevent further interfacial corrosion of the metal substrate. The base layer consisting of TiTaOₓ oxide layer may be applied instead of the AIP base layer.

The catalyst layer was formed in such a manner that hydrochloric acid aqueous solution of IrCl₃/Ta₂Cl₅ As a coating liquid was coated on the AIP coated titanium substrate at 1.1 g-Ir/m² per time and baked at a temperature by which part of IrO₂ crystallizes (410° C.-450° C.). After repeating the coating and baking process until the necessary support amount of the catalyst was obtained, one hour post-bake was conducted at a further high temperature (520° C.-560° C.). In this way, the electrode sample was prepared. The prepared sample was measured for IrO₂ crystalline of the catalyst layer by X-ray diffraction, oxygen generation overvoltage, electrostatic capacity of electrode, etc. and evaluated for sulfuric acid electrolysis and gelatin-added sulfuric acid electrolysis and lead adherence test.

As a result, it has been found that in case iridium oxide of the catalyst layer was formed by a baking in a high temperature region of 410° C.-450° C. and the post-baking in a further high temperature region of 520° C.-560° C., the most of iridium oxide of the formed catalyst layer was crystalline, the crystallite diameter became smaller, and the electrode effective surface area increased. The oxygen generation overvoltage was reduced up to approximately 50 mV by conventional products at the same time, too. After examining lead adhesion, a quantity of lead adhesion became 1/10 of conventional products on the lowest mark, and a suppressant effect of good lead adhesion was recognized. In addition, sulfuric acid electrolysis life was at the same class that of conventional products, proving improvement in durability.

The experimental conditions and methods by the present invention are as follows.

The sample manufacturing procedures were as follows.

### (1) Preparation of AIP Substrate

Ultrasonic cleaning: Detergent+alcohol, 15 minutes

Drying: 60° C., more than 1 hour

Etching: 20% HCl aq. 60° C., 20 minutes

Drying: 60° C., more than 1 hour

Baking: 180° C., 3 hours

### (2) AIP Coating

The cleaned metal substrate of the electrode was set to the AIP unit applying Ti—Ta alloy target as a vapor source and a coating of tantalum and titanium alloy was applied as the base layer on the surface of the metal substrate of the electrode. Coating condition is shown in Table 1.

TABLE 1

| | |
|---|---|
| Target(vapor source) | Alloy disk comprising |
| | Ta:Ti = 60 wt %:40 wt % |
| | (back surface cooling) |
| Vacuum pressure | 1.5 × 10⁻² Pa or less |
| Metal substrate temperature | 500° C. or lower |
| Coating pressure | 3.0 × 10⁻¹~4.0 × 10⁻¹ Pa |
| Vapor source charge power | 20~30 V, 140~160 A |
| Coating time | 15~20 minutes |
| Coating thickness | 2 μm(weight increase |
| | conversion) |

### (3) Catalyst Layer Coating

Coating solution: Ir/Ta=65:35, it is a hydrochloric acid water solution.

Rotary coating: 650 rpm, 1 minute

Room temperature drying: 10 minutes

Dryer drying: 60° C., 10 minutes

Muffle furnace: 15 minutes

Cooling: Electric fan, 10 minutes

Coting times: 12 times

Post Baking: 1 hour

Manufacturing conditions of samples, degree of crystallinity, crystallite diameter, electrostatic capacity and oxygen generation overvoltage are shown in Table 2.

TABLE 2

| | | | | | | | Oxygen generation |
|---|---|---|---|---|---|---|---|
| | | Top coating | Post-baking | Degree of | Crystallite | Electrostatic | overvoltage |
| | | temperature | temperature | crystallinity | diameter | capacity | (V vs. SSE |
| Sample No. | Base | (° C.) | (1 h) (° C.) | (%) | (nm) | (C/m²) | @100 A/dm²) |
| 1 | Ti/AlP | 410 | none | 25 | 8.1 | 21.1 | 0.926 |
| 2 | 530° C. × | | 520 | 96 | 7.9 | 12.7 | 1.005 |
| 3 | 180 min | | 560 | 86 | 6.7 | 11.3 | 1.034 |
| 4 | | 430 | none | 67 | 9.1 | 16.1 | 0.962 |
| 5 | | | 520 | 95 | 9.1 | 12.2 | 1.015 |
| 6 | | | 560 | 100 | 9.0 | 10.1 | 1.035 |
| 7 | | 450 | none | 76 | 10.1 | 8.7 | 1.000 |
| 8 | | | 520 | 100 | 9.3 | 10.8 | 1.039 |
| 9 | | | 560 | 100 | 9.7 | 9.6 | 1.043 |
| 10 | | 480 | none | 100 | 10.4 | 6.0 | 1.054 |
| 11 | | | 520 | 100 | 10.6 | 4.7 | 1.076 |
| 12 | | | 560 | 100 | 10.7 | 5.1 | 1.087 |
| 13 (Conven- | | 500-520 | none | 100 | 10.7 | 5.4 | 1.066 |
| tional product) | | | | | | | |

Experimental Items for Evaluation

### (1) Degree of Crystallinity and Measurement of Crystallite Diameter

IrO₂ crystallinity and crystallite diameter of the catalyst layer were measured by X-rays diffractometry.

The degree of crystallinity was estimated from the diffraction peak intensity.

### (2) Electrostatic Capacity of Electrode

Method: Cyclic voltammetry

Electrolyte: 150 g/L H₂SO₄ Aq.

Electrolysis temperature: 60° C.

Electrolysis area: 10×10 mm²

Counter electrode: Zr plate (20 mm×70 mm)

Reference electrode: Mercurous sulphate electrode (SSE)

### (3) Measurement of Oxygen Overvoltage

Method: Current interrupt method

Electrolyte: 150 g/L H₂SO₄ Aq.

Electrolysis temperature: 60° C.

Electrolysis area: 10×10 mm²

Counter electrode: Zr plate (20 mm×70 mm)

Reference electrode: Mercurous sulphate electrode (SSE)

### (4) Lead Adhesion Examination Evaluation

Evaluation by consecutive electrolysis in flow cells was carried out.

Electrolyte: 100 g/L H₂SO₄ Aq.

Additive: 7 ppm Pb²⁺ (PbCO₃), 150 ppmSb³⁺ (Sb₂O₃), 40 ppmCo²⁺ (CoSO₄), 10 ppm gelatin

Electrolysis temperature: 60° C.

Current density: 80 A/dm²

Electrolysis area: 20×20 mm²

Cathode: Zr plate (20×20 mm)

Electrolysis time: 130 hours

The measurement of the adhesion amount: An anode regularly was taken out and adhesion amount was calculated by the anodic weight change.

### (5) Acceleration Life Evaluation (Sulfuric Acid Solution)

An electrolyte: 150 g/H₂SO₄ Aq.

Electrolysis temperature: 60° C.

Current density: 500 A/dm² (in pure sulfuric acid solution)

Electrolysis area: 10×10 mm²

### (6) Acceleration Life Evaluation (Sulfuric Acid+Gelatin Solution)

Electrolyte: 150 g/L H₂SO₄ Aq. which added 50 ppm gelatin

Electrolysis temperature: 60° C.

Current density: 300 A/dm² (sulfuric acid+gelatin solution)

Electrolysis area: 10×10 mm²

The results of the above experiment are as follows.

The changes of IrO₂ crystal characteristics by the baking temperature and the post-bake temperature were as shown in Table 2.

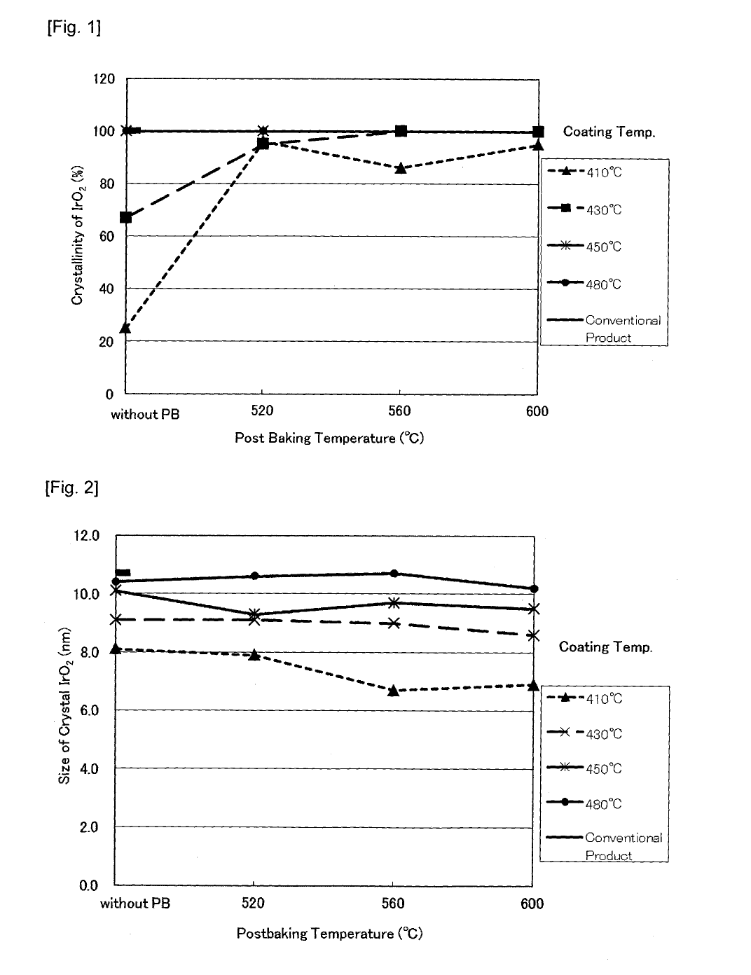

FIG. 1 is a graph showing the degree of crystallinity based on the data in Table 2 and FIG. 2 is a graph showing crystallite diameter based on the data in Table 2. As is clear from Table 2 And FIGS. 1 and 2, the degree of crystallite diameter of samples after being post baked in the high temperature region of 520° C.-560° C. was not changed by increasing of a temperature of post baking and became small in comparison with conventional products. In other words, by post baking in the high temperature region of 520° C.-560° C., almost all of iridium oxides of the catalyst layer was completely crystallized, but the growth of the crystallite diameter was restrained in comparison with conventional products.

As clearly shown from Table 2, FIGS. 1 and 2, the degree of crystallinity of iridium oxides after the post-baking of samples 2, 3, 5, 6, 8 And 9 were 80% or more. On the other hand, it was confirmed that the degree of crystallinity of iridium oxides in the electrode catalyst layer without the post-baking (samples 1 And 4) were low and was respectively 25% and 67% and almost all of the catalyst layer was formed from amorphous iridium oxide. In addition, sample 7, which is the electrode catalyst layer without the post baking, was showing the degree of crystallinity being 76%, but the crystallite diameter increases to 10.1 nm, resulting in a low value of the electrostatic capacity of electrode. The samples (sample 10-12) which was baked at 480° C. and sample 13 which is conventional product were fully crystallized, showing the degree of crystallinity being 100%, but the crystallite diameter increases to 10.7 nm, resulting in a low value of the electrostatic capacity of electrode.

As for the estimation of degree of crystallinity, the intensity of the crystal diffraction peak (2θ=28 degrees) of each sample is expressed as a ratio when compared with the intensity of the crystal diffraction peak (2θ=28 degrees) of the conventional product which is assumed as 100%. Firstly, each sample was baked at a relatively high temperature region of 410° C.-450° C. to form the catalyst layer coexisting amorphous and crystalline iridium oxides and the catalyst layer coexisting the amorphous and crystalline iridium oxides was post-baked in a further high temperature region of 520° C.-560° C. to crystallize almost all amount of iridium oxide in the catalyst layer. On the other hand, it was found that a small amount of amorphous iridium oxide IrO₂ was remained in the catalyst layer after post baking.

Then, measurements were made about the change of the electrode effective surface area of the electrode catalyst layer prepared by high temperature baking in a relatively high temperature region of 410° C.-450° C. and post-bake in a further high temperature region of 520° C.-560° C.

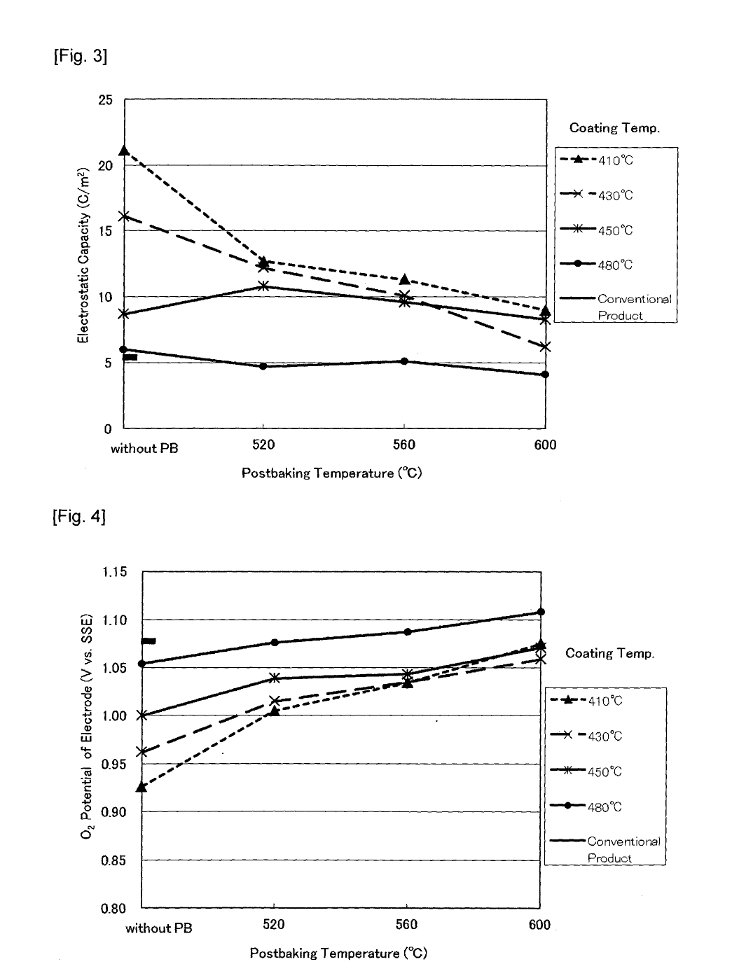

Electrostatic capacity of the electrode calculated by the cyclic voltammetry method is shown as data of Electrostatic capacity in Table 2 And in FIG. 3. As is clear from the results, it was found that the electrostatic capacity of the electrode of Samples 2, 3, 5, 6, 8, 9, which were subjected to baking in a relatively high temperature region of 410° C.-450° C. and post-bake in a further high temperature region of 520° C.-560° C., remarkably increased, compared with a conventional product (sample 13) and also the effective surface area of electrode increased, that is, the electrode effective surface area of the above electrode was increased.

A part of IrO₂ of the catalyst layer formed by baking at 410° C., 430° C. and 450° C. without post-bake showed the largest electrode effective surface area, since it is amorphous. On the other hand, in case that the catalyst layer formed by baking at 410° C., 430° C. and 450° C. was conducted post-bake, the electrode effective surface area decreased since IrO₂ was crystallized, but it was still higher compared with the conventional product. The reason is considered that the crystallite diameter of formed iridium oxide is small, compared with the conventional product and a small amount of an amorphous iridium oxide exists. Namely, it was observed that the electrode effective surface area of the catalyst layer formed by baking at 410° C., 430° C. and 450° C. on which post baking was conducted increased, compared with the conventional product and an oxygen evolution overvoltage decreased.

Also, it has been found that if post-bake is not conducted after the baking at 480° C. or higher, the electrode effective surface area decreased since a crystallinity of the iridium oxide increased. Furthermore, if the post baking is conducted, it is found that the electrode effective surface area tends to decrease further, but even if the post-bake temperature is increased, there was no change in the electrode effective surface area. It is considered that the reason why even if the post-bake temperature as mentioned before is increased, both of the degree of crystallinity and the crystallite diameter of IrO₂ Are not largely changed. On the other hand, in case of a baking of a temperature of 480° C., it was found that the electrode effective surface area was similar to that of the conventional products with or without post-baking.

The dependency of a baking condition and an oxygen generation overvoltage are shown in Table 2 And FIG. 4. Namely, being accompanied by an increase of the electrode effective surface area, an oxygen generation overvoltage was deducted compared with the conventional product (sample 13). It was found that the oxygen generation overvoltage was deducted maximum 61 mV by a baking at in a relatively high temperature region of 410° C.-450° C. and a post baking in a further high temperature region of 520° C.-560° C. The trend of changing in the graph of FIG. 4 was reverse to that of FIG. 3. With increase of the electrode effective surface area, the oxygen generation overvoltage of the samples tended to decrease. It is considered that these low oxygen generation overvoltage electrodes have a suppression effect to lead adhesion.

### EXAMPLES

The following describes examples by the present invention, however, the present invention is not limited to these examples.

### Example 1

The surface of titanium plate (JIS-I) was subjected to the dry blast with iron grit (G120 size), followed by pickling in an aqueous solution of concentrated hydrochloric acid for 10 minutes at the boiling point for cleaning treatment of the metal substrate of the electrode. The cleaned metal substrate of the electrode is set to the AIP unit applying Ti—Ta alloy target as a vapor source and a coating of tantalum and titanium alloy was applied as the AIP base layer on the surface of the metal substrate of the electrode. Coating condition is shown in Table 1.

The coated metal substrate was treated at 530° C. in an electric furnace of air circulation type for 180 minutes.

Then, the coating solution prepared by dissolving iridium tetrachloride and tantalum pentachloride in concentrated hydrochloric acid is applied on the coated metal substrate. After drying, the thermolysis coating was conducted for 15 minutes in the electric furnace of air circulation type at 430° C. to form an electrode catalyst layer comprising mixture oxides of iridium oxide and tantalum oxide. The amount of coating solution was determined so that the thickness of coating per time of the coating solution corresponds to approx. 1.1 g/m², as iridium metal. This coating-baking operation was repeated twelve times to obtain the electrode catalyst layer of approx. 13.2 g/m², as iridium metal.

The X-ray diffraction was carried out for this sample. A clear peak of iridium oxide attributable to the electrode catalyst layer was observed, but the intensity of the peak was lower than that of Comparative Example 1, indicating that crystalline IrO₂ had been partially precipitated. The crystalline diameter calculated from the crystal diffraction peak was relatively low compared with the conventional product.

Next, an electrode for electrolysis was manufactured in such a manner that the sample coated with the catalyst layer is post-baked in an electric furnace of air circulation type at 520° C. for one hour.

The X-ray diffraction was carried out for the sample with post-baking. A clear peak of iridium oxide attributable to the electrode catalyst layer was observed, but the intensity of the peak was similar to that of Comparative Example 1. From this, it has been known that an amorphous IrO₂ remained in the coating process by the lower temperature baking before a high temperature post baking was crystallized.

About the electrode for electrolysis prepared in the above-mentioned manner, the afore-mentioned lead adhesion test and accelerated life evaluation test (Pure sulfuric acid solution and sulfuric acid solution with gelatin) were conducted. Results are shown in Table 3. When compared with the Comparative Example 1 (Conventional Product) in Table 3, the amount of lead adhesion was one-tenth and both of the life for sulfuric acid electrolysis and gelatin-added sulfuric acid electrolysis were increased and then it was found that a lead adhesion to the electrode and a durability to organic additive in both of the life for sulfuric acid electrolysis and gelatin-added sulfuric acid electrolysis have been improved.

TABLE 3

| | | | | | Accelerated life | Amount of |
|---|---|---|---|---|---|---|
| | | Baking | Post-bake | Accelerated life | of electrolysis | a lead |
| | | temperature | temperature | of electrolysis | (gelatin-added | adhesion |
| | | (° C.) | (° C.) | (Sulfuric acid) (hr) | sulfuric acid) (hr) | (g/m² Ti) |
| Example | 1 | 430 | 520 | 1781 | 309 | 11 |
| | 2 | 430 | 560 | 1537 | 315 | 90 |
| Comparative | 1 | 520 | — | 1506 | 280 | 120 |
| Example | 2 | 430 | 600 | 1654 | 293 | 108 |

### Example 2

The electrode for evaluation was manufactured in the same manner as with Example 1 except that post-bake was conducted in an electric furnace of air circulation type for one hour at 560° C. and the same electrolysis evaluation was performed.

The X-ray diffraction performed after post-bake showed the degree of crystallinity and crystallite diameter of IrO₂ in the catalyst layer equivalent to Example 1.

As shown in Table 3, an amount of a lead adhesion to the electrode of Example 2 is three-fourth to that of the Comparative Example 1 And a suppression effect of the lead adhesion was confirmed. In addition, the life of sulfuric acid electrolysis and gelatin-added sulfuric acid electrolysis was increased and their durability has also have been improved.

### Comparative Example 1

The electrode catalyst layer comprising the mixture oxide of iridium oxide and tantalum oxide was formed as with Example 1, but changing the baking temperature in the electric furnace of circulation air type to 520° C. and the baking time to fifteen minutes. The electrode thus manufactured without post-bake was evaluated for electrolysis by the X-ray diffraction as with Example 1.

The X-ray diffraction was performed on this sample, from which a clear peak of iridium oxide attributable to the electrode catalyst layer was observed, verifying that IrO₂ in the catalyst layer is crystalline. However, from a result of a lead adhesion test as similar to the Example 1, a life of an accelerated electrolysis test of the electrode of the comparative Example 1 was short and 1506 hours and an amount of a lead adhesion was 120 g/m² As shown in Table 3.

### Comparative Example 2

In the same manner as with Example 1 except that post-bake was carried out at 600° C. and 1 hour, the electrode for evaluation was manufactured and electrolysis evaluation was carried out in the same manner with Example 1.

From the results of the X ray diffraction after post baking, the degree of a crystallinity and a crystalline diameter of iridium oxides of the catalyst layer are almost same as that of Example 1, but as a result of an electrolysis evaluation, as shown in Table 3, lives of the electrode for sulfuric acid electrolysis and gelatin-added sulfuric acid electrolysis were equivalent to that of the Comparative Example 1. In addition, an amount of a lead adhesion is much and similar to that of the Comparative Example 1 And a suppression effect was not found. It is considered that a temperature of the post baking is high as 600° C.

As shown in the above experimental results, by the present invention, the electrode surface area increased and an oxygen generation over voltage decreased, compared with the conventional product, by means of a baking in a relatively high temperature region of 410° C.-450° C. and a post baking in a further high temperature region of 520° C.-600° C. Accordingly, by promoting the oxygen generation reaction, a suppression effect of a lead adhesion was performed simultaneously. Furthermore, since iridium oxides of the catalyst layer mainly exist as a crystalline, a durability of the electrode was performed.

### INDUSTRIAL APPLICABILITY

The present invention relates to an anode for oxygen generation used for various industrial electrolyses and a manufacturing method for the same; more in detail, it is applicable to an anode for oxygen generation used for industrial electrolyses including manufacturing of electrolytic metal foils such as electrolytic copper foil, aluminum liquid contact, continuously electrogalvanized steel plate and metal extraction.

1. An anode for oxygen generation comprising a conductive metal substrate and a catalyst layer containing iridium oxide formed on the conductive metal substrate, wherein the coating layer is baked in a high temperature region of 410° C.-450° C. in an oxidation atmosphere to form the catalyst layer co-existing amorphous and crystalline iridium oxide and the catalyst layer coexisting the amorphous and crystalline iridium oxide is post-baked in a further high temperature region of 520° C.-560° C. in an oxidation atmosphere to crystallize almost all amount of iridium oxide in the catalyst layer.

2. The anode for oxygen generation as in claim 1, comprising the conductive metal substrate and the catalyst layer containing iridium oxide formed on the conductive metal substrate, wherein the degree of crystallinity of iridium oxide in the catalyst layer after the post-bake is made to be 80% or more.

3. The anode for oxygen generation, as in claim 1, comprising the conductive metal substrate and the catalyst layer containing iridium oxide formed on the conductive metal substrate, wherein the crystallite diameter of iridium oxide in the catalyst layer after the post-baking is made to be 9.7 nm or less.

4. The anode for oxygen generation, as in claim 1, comprising the conductive metal substrate and the catalyst layer containing iridium oxide formed on the conductive metal substrate, wherein an arc ion plating base layer containing tantalum and titanium ingredients is formed by the arc ion plating process on the conductive metal substrate before the formation of the catalyst layer.

5. A manufacturing method for an anode for oxygen generation comprising:
forming on a catalyst layer co-existing amorphous and crystalline iridium oxide surface of a conductive metal substrate by baking in a high temperature region of 410° C.-450° C. in an oxidation atmosphere and the catalyst layer co-existing amorphous; and
post-baking crystalline iridium oxide in a further high temperature region of 520° C.-560° C. in an oxidation atmosphere to crystallize almost all amount of iridium oxide in the catalyst layer.

6. The manufacturing method for the anode for oxygen generation, as in claim 5, wherein the catalyst layer co-existing amorphous and crystalline iridium oxide is formed on the surface of the conductive metal substrate by baking in a high temperature region of 410° C.-450° C. in an oxidation atmosphere and the catalyst layer co-existing amorphous and crystalline iridium oxide is post-baked in a further high temperature region of 520° C.-560° C. in an oxidation atmosphere to make the degree of crystallinity of iridium oxide in the catalyst layer to be 80% or more.

7. The manufacturing method for the anode for oxygen generation, as in claim 5, wherein the catalyst layer co-existing amorphous and crystalline iridium oxide is formed on the surface of the conductive metal substrate by baking in a high temperature region of 410° C.-450° C. in an oxidation atmosphere and the catalyst layer co-existing amorphous and crystalline iridium oxide is post-baked in a further high temperature region of 520° C.-560° C. in an oxidation atmosphere to make the crystallite diameter of iridium oxide in the catalyst layer to be 9.7 nm or less.

8. The manufacturing method for the anode for oxygen generation, as in claim 5, comprising the conductive metal substrate and the catalyst layer containing iridium oxide formed on the conductive metal substrate, wherein the arc ion plating base layer containing tantalum and titanium ingredients is formed by the arc ion plating process on the conductive metal substrate before the formation of the catalyst layer.
